(19) United States
(12) Patent Application Publication
(10) Pub. No.: US 2025/0210407 A1
(43) Pub. Date: Jun. 26, 2025

(54) APPARATUS FOR A SUBSTRATE SUPPORT WITH MULTI-ZONE CONTROL

(71) Applicant: ASM IP Holding B.V., Almere (NL)

(72) Inventors: Shubham Garg, Gilbert, AZ (US); Hang Zhang, Tempe, AZ (US); Todd Robert Dunn, Cave Creek, AZ (US); Rajmohan Muthaiah, Phoenix, AZ (US); Pawan Sharma, Tempe, AZ (US)

(21) Appl. No.: 18/985,379

(22) Filed: Dec. 18, 2024

Related U.S. Application Data
(60) Provisional application No. 63/613,195, filed on Dec. 21, 2023.

(51) Int. Cl. H01L 21/687

(52) U.S. Cl. CPC H01L 21/68785; H01L 21/68757

(57) ABSTRACT

Various embodiments of the present technology may provide a substrate support apparatus with a surface having a first region with a first temperature profile, a second region having a second temperature profile; and a third region having a third temperature profile. The substrate support apparatus may also have a first channel embedded within the body and disposed between the first region and the second region, and a second channel disposed between the second region and the third region.

### CROSS-REFERENCE TO RELATED APPLICATIONS

This application is a nonprovisional of, and claims priority to and the benefit of, U.S. Provisional Patent Application No. 63/613,195, filed Dec. 21, 2023 and entitled “APPARATUS FOR A SUBSTRATE SUPPORT WITH MULTI-ZONE CONTROL,” which is hereby incorporated by reference herein.

### FIELD OF INVENTION

The present disclosure generally relates to an apparatus for a substrate support with multi-zone control. More particularly, the present disclosure relates to a substrate support with a plurality of temperature profiles.

### BACKGROUND OF THE TECHNOLOGY

Some reaction chambers used in semiconductor manufacturing utilize a substrate support apparatus to hold a substrate, such as a wafer during processing. The substrate support apparatus may also be used to heat the wafer to a desired temperature. Conventional substrate supports may not provide the desired temperature profile for a particular process. Accordingly, it may be desired to have a substrate support with multi-zone temperature control.

### SUMMARY OF THE INVENTION

Various embodiments of the present technology may provide a substrate support apparatus with a surface having a first region with a first temperature profile, a second region having a second temperature profile; and a third region having a third temperature profile. The substrate support apparatus may also have a first channel embedded within the body and disposed between the first region and the second region, and a second channel disposed between the second region and the third region.

According to one aspect, a substrate support apparatus comprises: a body, formed from a ceramic material, comprising a first surface and an opposing second surface; wherein the first surface comprises: a first region having a first contact resistance and a first temperature profile; a second region having a second contact resistance and a second temperature profile; and a third region having a third contact resistance and a third temperature profile; a pedestal coupled to the second surface; a plurality of channels embedded within the body and comprising: a first channel disposed between the first region and the second region; and a second channel disposed between the second region and the third region; and a plurality of heating elements embedded within the body.

In one embodiment, the first, second, and third regions are concentric.

In one embodiment, the first region is located at a geometric center of the body, the second region is radially outward from the first region, and the third region is radially outward from the second region.

In one embodiment, the first region has a first surface area and is formed from a first material having a first emissivity; the second region has a second surface area and is formed from a second material having a second emissivity, wherein the second material is different from the first material; and the third region has a third surface area and is formed from a third material having a third emissivity, wherein the third material is different from the second material.

In one embodiment, the apparatus further comprises a plurality of electrodes embedded within the body and located above the plurality of heating elements, and wherein the body is formed from a ceramic material comprising one of AlN, SiC, SiN, AlOx, and BeC.

In one embodiment, the plurality of channels are concentric.

In one embodiment, the plurality of channels are capable of containing at least one of air and helium.

According to another aspect, a substrate support apparatus comprises: a body, formed from a ceramic material, comprising a first surface and an opposing second surface; wherein the first surface comprises: a first region having a first temperature profile, a second region having a second temperature profile; and a third region having a third temperature profile; a pedestal coupled to the second surface; and a plurality of heating elements embedded within the body.

In one embodiment, the first, second, and third regions are concentric.

In one embodiment, the first region is located at a geometric center of the body, the second region is radially outward from the first region, and the third region is radially outward from the second region.

In one embodiment, the first region has first surface area having a first roughness, the second region has a second surface area having a second roughness, and the third region has a third surface area having a third roughness, wherein the first, second, and third roughness differ from each other.

In one embodiment, the apparatus further comprises a plurality of electrodes embedded within the body and located above the plurality of heating elements, and wherein the body is formed from a ceramic material comprising one of AlN, SiC, SiN, AlOx, and BeC.

In one embodiment, the first region has a first surface area and is formed from a first material having a first emissivity; the second region has a second surface area and is formed from a second material having a second emissivity, wherein the second material is different from the first material; and wherein the third region has a third surface area and is formed from a third material having a third emissivity, wherein the third material is different from the second material.

In yet another aspect, a system comprises: a substrate support apparatus comprising: a body comprising a first surface and an opposing second surface; and a cap disposed on the first surface of the body and comprising an outward-facing surface comprising: a first region having a first contact resistance, a second region having a second contact resistance; and a third region having a third contact resistance; a pedestal coupled to the second surface; and a plurality of heating elements embedded within the body.

In one embodiment, the first, second, and third regions are concentric.

In one embodiment, the first region is located at a geometric center of the body, the second region is radially outward from the first region, and the third region is radially outward from the second region.

In one embodiment, the cap further comprises a plurality of channels comprising: a first channel disposed between the first region and the second region; and a second channel disposed between the second region and the third region.

In one embodiment, the system further comprises a helium source coupled to the plurality of channels.

In one embodiment, the first region has a first temperature profile, the second region has a second temperature profile, and the third region has a third temperature profile, wherein the first, second, and third temperature profiles differ from each other.

In one embodiment, the first region has a first surface area, the second region has a second surface area, and the third region has a third surface area, wherein the first, second, and third surface areas differ from each other.

### BRIEF DESCRIPTION OF THE DRAWING FIGURES

A more complete understanding of the present technology may be derived by referring to the detailed description when considered in connection with the following illustrative figures. In the following figures, like reference numbers refer to similar elements and steps throughout the figures.

FIG. 1 representatively illustrates a system in accordance with embodiments of the present technology;

FIG. 2 is a top view of a substrate support in accordance with embodiments of the present technology;

FIG. 3 is a cross-sectional view of the substrate support of FIG. 2 in accordance with embodiments of the present technology;

FIG. 4 is a sectional top view of a substrate support in accordance with embodiments of the present technology;

FIG. 5 is a cross-sectional view of the substrate support of FIG. 4 in accordance with embodiments of the present technology;

FIG. 6 is a cross-sectional view of a substrate support in accordance with embodiments of the present technology; and

FIG. 7 is a cross-sectional view of a substrate support in accordance with embodiments of the present technology.

### DETAILED DESCRIPTION OF EXEMPLARY EMBODIMENTS

The present technology may be described in terms of functional block components and various processing steps. Such functional blocks may be realized by any number of components configured to perform the specified functions and achieve the various results. For example, the present technology may employ various gas lines, vessels, reaction chambers, gas distribution systems, and pumps.

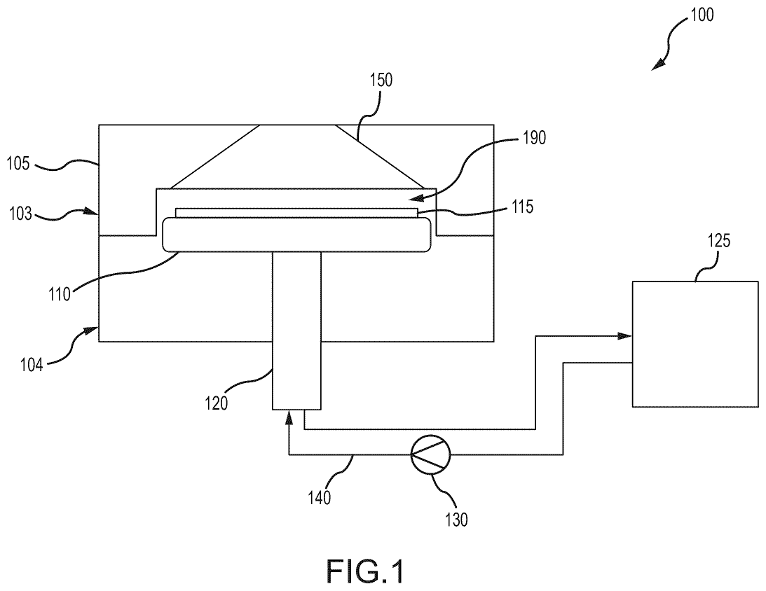

Referring to FIG. 1, an exemplary system 100 may comprise a reactor 105 comprising an upper body 103 and a lower body 104. The upper body 103 and the lower body 104 may be connected to each other. In more detail, the upper body 103 and the lower body 104 of the reactor 105 may form a reaction space 190 while face-contacting and face-sealing each other.

In various embodiments, the reactor 105 may be configured to perform processing on an object to be processed, such as a substrate 115 (e.g., a wafer). For example, the reactor 105 may be configured to perform heating, deposition, etching, polishing, ion implantation, and/or other processing on the object to be processed. In some embodiments, the reactor 105 may be configured to perform a movement function, a vacuum sealing function, a heating function, an exhaust function, and/or other functions for the object to be processed such that the object is processed in the reactor. In some embodiments, the reactor 105 may be a reactor in which an atomic layer deposition (ALD) or a chemical vapor deposition (CVD) process is performed.

In various embodiments, the upper boy 103 may comprise a gas distribution apparatus 150 configured to flow a vapor into the reaction space 190. The gas distribution apparatus 150 may comprise a plurality of through-holes (not shown) arranged directly above the substrate support apparatus 110.

In various embodiments, the system 100 may further comprise a gas source, such as a vessel 125 configured to contain a gas, such as a thermally conductive gas (e.g., helium). The vessel 125 may be coupled to the pedestal 120 and/or the substrate support apparatus 110 via a gas line 140. A pump 130 may be arranged between the vessel 125 and the pedestal 120 (and/or the substrate support apparatus 110) to facilitate the flow of the gas from the vessel 125 to the pedestal 120 (and/or the substrate support apparatus 110).

In various embodiments, the reactor 105 may include, in the reaction space 190, a substrate support apparatus 110 to support the substrate 115. The substrate support apparatus 110 may be supported by a pedestal 120. For example, the pedestal 120 may be coupled to a bottom surface of the substrate support apparatus 110. For loading/unloading of the substrate 115, the substrate support apparatus 110 may be configured to be vertically movable by being connected to a driving unit (not shown).

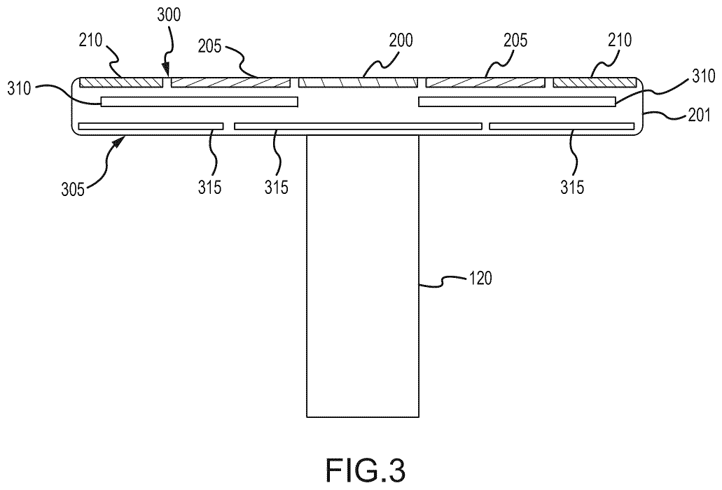

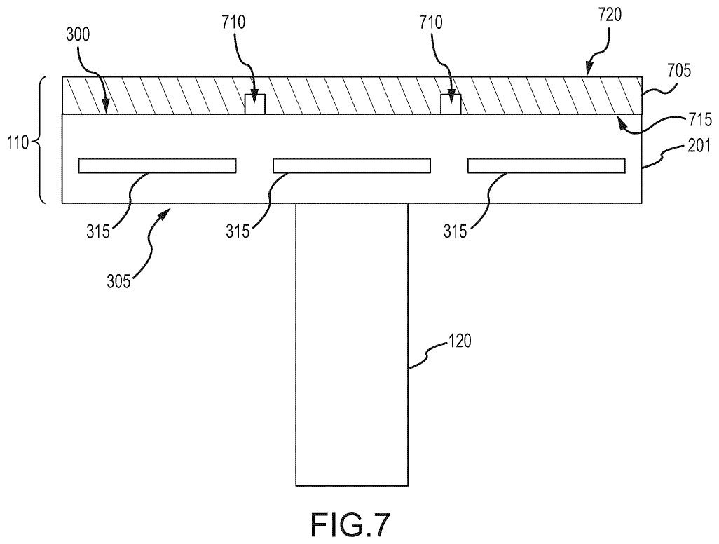

In various embodiments, and referring to FIGS. 3 and 7, the substrate support apparatus 110 may comprise a body 201. The body may be formed from a ceramic material, such as at least one of aluminum nitride (AIN), silicon carbide (SiC), silicon nitride (SiN), aluminum oxide (AlOx), and beryllium carbide (BeC). The body 210 may comprise a first surface 300 and an opposing second surface 305. For example, the first and second surfaces 300, 305 may be in parallel with each other. The pedestal 120 may be coupled to the second surface 305 of the body 201.

In various embodiments, the substrate support apparatus 110 may further comprise a cap 705. The cap 705 may comprise a first surface (i.e., an outward-facing surface) 720 and a second surface 715. The cap 705 may be disposed on the body 201. For example, the second surface 715 of the cap 705 may be disposed on and make direct contact with the first surface 300 of the body 201. The cap 705 may be formed from a metal material, such as Hastelloy, nickel, titanium. In other cases, the cap 705 may be formed from a ceramic material, such as aluminum nitride (AIN), silicon carbide (SiC), silicon nitride (SiN), aluminum oxide (AlOx), and beryllium carbide (BeC).

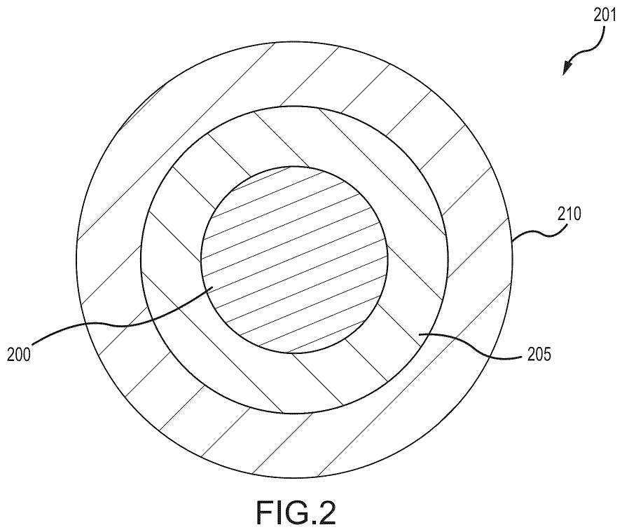

In various embodiments, and referring to FIGS. 2 and 3, the body 201 may provide a multi-zone temperature control, wherein each zone has a particular temperature profile. In an exemplary embodiment, the first surface 300 may comprise a first region 200 located in a geometric center of the body 210, a second region 205 located radially outward from and concentric with the first region 200, and a third region 210 located radially outward from and concentric with the second region 205.

In various embodiments, the temperature profile of each region may be varied based on a contact resistance of a surface. The contact resistance of a surface of each region, and thus the temperature profile of each region, may be varied based on surface area, emissivity, and surface roughness. For example, a higher temperature profile corresponds to a higher surface area, a higher emissivity, and a lower surface roughness (i.e., a smooth or polished surface). In contrast, a lower temperature profile corresponds to a lower surface area, lower emissivity, and a higher surface roughness. In some cases, each region may have a different temperature profile. However, in some cases, two or more regions may have the same temperature profile. For example, the first region 200 may have a first temperature profile according to a first surface area, a first emissivity, and a first surface roughness. The second region 205 may have a second temperature profile according to a second surface area, a second emissivity, and a second surface roughness. The third region 210 may have a third temperature profile according to a third surface area, a third emissivity, and a third surface roughness. The surface area may be measured in mm² and surface roughness may be measured in microns (μm).

Emissivity may be varied by utilizing materials with different thermal properties. For example, the first region 200 may be formed using a first material having a first emissivity, the second region 205 may be formed using a second material having a second emissivity, and the third region 210 may be formed using a third material having a third emissivity, wherein the emissivity of each material is different.

Additionally, or alternatively, the cap 705 may provide a multi-zone temperature control, wherein each zone has a particular temperature profile. For example, the cap 705 may comprise multiple zones, as described above. In an exemplary embodiment, the first surface 720 of the cap 705 may comprise the first region 200 located in a geometric center of the body 210, the second region 205 located radially outward from and concentric with the first region 200, and the third region 210 located radially outward from and concentric with the second region 205.

In various embodiments, the temperature profile of each region may be varied based on surface area, emissivity, and surface roughness. In some cases, each region may have a different temperature profile. However, in some cases, two or more regions may have the same temperature profile. For example, the first region 200 may have a first temperature profile according to a first surface area, a first emissivity, and a first surface roughness. The second region 205 may have a second temperature profile according to a second surface area, a second emissivity, and a second surface roughness. The third region 210 may have a third temperature profile according to a third surface area, a third emissivity, and a third surface roughness. The surface area may be measured in mm² and surface roughness may be measured in microns (μm).

Emissivity may be varied by utilizing materials with different thermal properties. For example, the first region 200 may be formed using a first material having a first emissivity, the second region 205 may be formed using a second material having a second emissivity, and the third region 210 may be formed using a third material having a third emissivity, wherein the emissivity of each material is different.

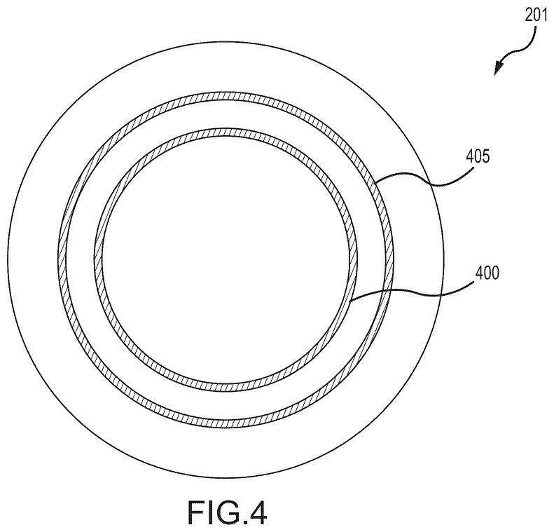

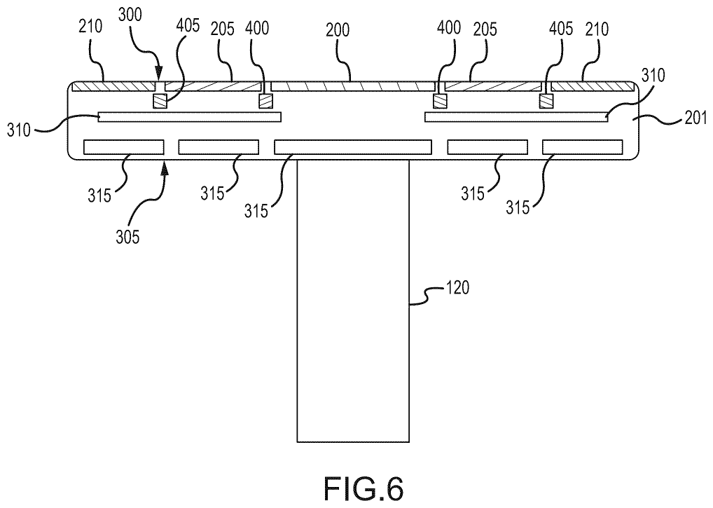

In various embodiments, and referring to FIGS. 1, 4-6, the body 201 may further comprise a plurality of channels, such a first channel 400 and a second channel 405, to provide a thermal break. The plurality of channels 400, 405 may be embedded within the body 201. In other words, the channels may be enclosed on all sides and capable of containing a gas. The first channel 400 may have a circular shape concentric with the geometric center of the body 201. The second channel 405 may be concentric with the first channel 400. The channels 400, 405 may have a square, circular, or any other suitable cross sectional shape. In various embodiments, the channels 400, 405 may have a cross sectional area in a range of 2 mm²-10 mm².

In various embodiments, the first channel 400 may be arranged between the first and second regions 200, 205. In other words, the first channel 400 may be positioned at or near a boundary of the first and second regions 200, 205. Similarly, the second channel 405 may be arranged between the second and third regions 205, 210. In other words, the second channel 405 may be positioned at or near a boundary of the second and third regions 205, 210.

In various embodiments, the channels 400, 405 may be coupled to the vessel 125 via the gas line 140. For example, the pump 130 may flow helium into the channels 400, 405 and circulate the helium gas to provide pulses of helium or constant flow of helium. Alternatively, the pump 130 may be used to facilitate the flow of air into the channels 400, 405. Similarly, the pump 130 may flow air into the channels and circulate the air to provide pulses of air or a constant flow of air.

Additionally, or alternatively, the cap 705 may comprise the plurality of channels 400, 405, as described above, embedded within the cap 705.

Alternatively, and referring to FIG. 7, the cap 705 may comprise a groove 710 at the second surface 715 of the cap 705 to provide a thermal break. For example, the groove 710 may extend into the cap 705 by a depth of 3 mm to 8 mm, or 10-25% of the overall thickness of the cap 705.

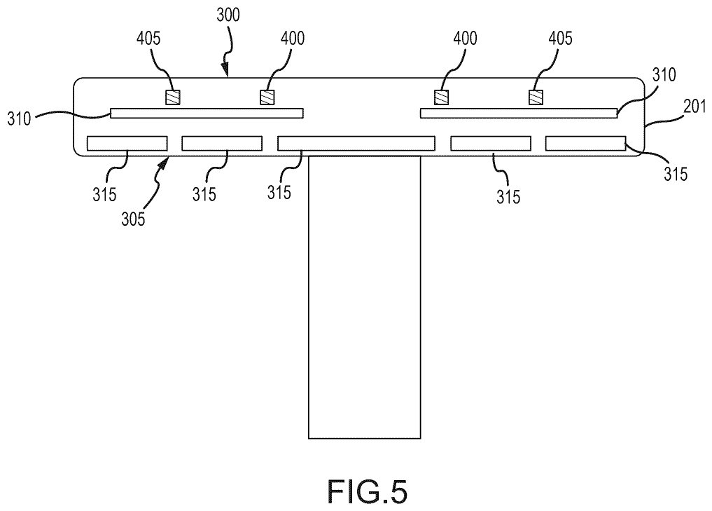

In various embodiments, and referring to FIGS. 5-7, the body 201 may further comprise a plurality of heating elements 315 embedded within the body 201. The heating elements may be arranged to correspond to the first, second and third regions. For example, a first heating element may be located directly below the first region 200, a second heating element may be located directly below the second region 205, and a third heating element may be located directly below the third region 210. The heating elements may be operated independently from each other. In various embodiments, the heating elements may comprise any suitable heating device and/or system.

In various embodiments, the substrate support apparatus 110 may be configured to perform an electrostatic chucking function. For example, the body 210 or the cap 705 may comprise a plurality of electrodes 310 configured for electrostatic chucking. The electrodes 310 may be embedded within the body 210 and arranged above the heating elements. Similarly, the electrodes 310 may be embedded within the cap 705.

In the foregoing description, the technology has been described with reference to specific exemplary embodiments. The particular implementations shown and described are illustrative of the technology and its best mode and are not intended to otherwise limit the scope of the present technology in any way. Indeed, for the sake of brevity, conventional manufacturing, connection, preparation, and other functional aspects of the method and system may not be described in detail. Furthermore, the connecting lines shown in the various figures are intended to represent exemplary functional relationships and/or steps between the various elements. Many alternative or additional functional relationships or physical connections may be present in a practical system. The technology has been described with reference to specific exemplary embodiments. Various modifications and changes, however, may be made without departing from the scope of the present technology. The description and figures are to be regarded in an illustrative manner, rather than a restrictive one and all such modifications are intended to be included within the scope of the present technology. Accordingly, the scope of the technology should be determined by the generic embodiments described and their legal equivalents rather than by merely the specific examples described above. For example, the steps recited in any method or process embodiment may be executed in any order, unless otherwise expressly specified, and are not limited to the explicit order presented in the specific examples. Additionally, the components and/or elements recited in any apparatus embodiment may be assembled or otherwise operationally configured in a variety of permutations to produce substantially the same result as the present technology and are accordingly not limited to the specific configuration recited in the specific examples.

Benefits, other advantages and solutions to problems have been described above with regard to particular embodiments. Any benefit, advantage, solution to problems or any element that may cause any particular benefit, advantage or solution to occur or to become more pronounced, however, is not to be construed as a critical, required or essential feature or component.

The terms “comprises”, “comprising”, or any variation thereof, are intended to reference a non-exclusive inclusion, such that a process, method, article, composition or apparatus that comprises a list of elements does not include only those elements recited, but may also include other elements not expressly listed or inherent to such process, method, article, composition or apparatus. Other combinations and/or modifications of the above-described structures, arrangements, applications, proportions, elements, materials or components used in the practice of the present technology, in addition to those not specifically recited, may be varied or otherwise particularly adapted to specific environments, manufacturing specifications, design parameters or other operating requirements without departing from the general principles of the same.

The present technology has been described above with reference to an exemplary embodiment. However, changes and modifications may be made to the exemplary embodiment without departing from the scope of the present technology. These and other changes or modifications are intended to be included within the scope of the present technology, as expressed in the following claims.

What is claimed is:

1. A substrate support apparatus, comprising:
a body, formed from a ceramic material, comprising a first surface and an opposing second surface; wherein the first surface comprises:
a second region having a second contact resistance and a second temperature profile; and
a third region having a third contact resistance and a third temperature profile;
a pedestal coupled to the second surface;
a plurality of channels embedded within the body and comprising:
a first channel disposed between the first region and the second region; and
a second channel disposed between the second region and the third region; and
a plurality of heating elements embedded within the body.

2. The substrate support apparatus according to claim 1, wherein the first, second, and third regions are concentric.

3. The substrate support apparatus according to claim 1, wherein the first region is located at a geometric center of the body, the second region is radially outward from the first region, and the third region is radially outward from the second region.

4. The substrate support apparatus according to claim 1, wherein:
the first region has a first surface area and is formed from a first material having a first emissivity;
the second region has a second surface area and is formed from a second material having a second emissivity, wherein the second material is different from the first material;
and the third region has a third surface area and is formed from a third material having a third emissivity, wherein the third material is different from the second material.

5. The substrate support apparatus according to claim 1, further comprising a plurality of electrodes embedded within the body and located above the plurality of heating elements, and wherein the body is formed from a ceramic material comprising one of AlN, SiC, SiN, AlOx, and BeC

6. The substrate support apparatus according to claim 1, wherein the plurality of channels are concentric.

7. The substrate support apparatus according to claim 1, wherein the plurality of channels are capable of containing at least one of air and helium.

8. A substrate support apparatus, comprising:
a body, formed from a ceramic material, comprising a first surface and an opposing second surface; wherein the first surface comprises:
a first region having a first temperature profile,
a second region having a second temperature profile; and
a third region having a third temperature profile;
a pedestal coupled to the second surface; and
a plurality of heating elements embedded within the body.

9. The substrate support apparatus according to claim 8, wherein the first, second, and third regions are concentric.

10. The substrate support apparatus according to claim 8, wherein the first region is located at a geometric center of the body, the second region is radially outward from the first region, and the third region is radially outward from the second region.

11. The substrate support apparatus according to claim 8, wherein: the first region has first surface area having a first roughness, the second region has a second surface area having a second roughness, and the third region has a third surface area having a third roughness, wherein the first, second, and third roughness differ from each other.

12. The substrate support apparatus according to claim 8, further comprising a plurality of electrodes embedded within the body and located above the plurality of heating elements, and wherein the body is formed from a ceramic material comprising one of AIN, SiC, SiN, AlOx, and BeC.

13. The substrate support apparatus according to claim 8, wherein:
the first region has a first surface area and is formed from a first material having a first emissivity;
the second region has a second surface area and is formed from a second material having a second emissivity, wherein the second material is different from the first material; and
wherein the third region has a third surface area and is formed from a third material having a third emissivity, wherein the third material is different from the second material.

14. A system, comprising:
a substrate support apparatus comprising:
a body comprising a first surface and an opposing second surface; and
a cap disposed on the first surface of the body and comprising an outward-facing surface comprising:
a first region having a first contact resistance,
a second region having a second contact resistance; and
a third region having a third contact resistance;
a pedestal coupled to the second surface; and
a plurality of heating elements embedded within the body.

15. The system according to claim 14, wherein the first, second, and third regions are concentric.

16. The system according to claim 14, wherein the first region is located at a geometric center of the body, the second region is radially outward from the first region, and the third region is radially outward from the second region.

17. The system according to claim 14, wherein the cap further comprises a plurality of channels comprising:
a first channel disposed between the first region and the second region; and
a second channel disposed between the second region and the third region.

18. The system according to claim 17, further comprising a helium source coupled to the plurality of channels.

19. The system according to claim 14, wherein the first region has a first temperature profile, the second region has a second temperature profile, and the third region has a third temperature profile, wherein the first, second, and third temperature profiles differ from each other.

20. The system according to claim 14, wherein the first region has a first surface area, the second region has a second surface area, and the third region has a third surface area, wherein the first, second, and third surface areas differ from each other.
